(19) United States
(12) Patent Application Publication
(10) Pub. No.: US 2006/0275556 A1
(43) Pub. Date: Dec. 7, 2006

(54) Method for depositing an amorphous layer primarily containing fluorine and carbon, and device suited for carrying out this method

(76) Inventors: Karin Scherer, St. Maur des Fosses (FR); Pascale Lacan, Paris (FR); Richard Bosmans, Noiseau (FR)

Correspondence Address: YOUNG & THOMPSON, 745 SOUTH 23RD STREET, 2ND FLOOR, ARLINGTON, VA, 22202, US

(21) Appl. No.: 10/567,650

(22) PCT Filed: Sep. 2, 2004
(86) PCT No.: PCT/FR04/02242

§ 371 Date: Apr. 17, 2006

(30) Foreign Application Priority Data
Sep. 4, 2003 (FR) 0310472
Sep. 25, 2003 (FR) 0311238

(51) Int. Cl. C23C 14/00; C23C 8/00; C23C 16/00

(52) U.S. Cl. 427/523; 427/585; 118/723 MP

(57) ABSTRACT

A method for depositing, under vacuum, an amorphous layer primarily containing fluorine and carbon onto a substrate (9), characterized in that it comprises a step for depositing this layer with an ion gun (1) for ejecting ions in the form of a beam of accelerated ions that is created from at least one compound containing fluorine and carbon in a gaseous form or saturated vapor supplied to the ion canon. A method of this type makes it possible, in particular, to improve the adherence of an outer layer having a low index of refraction to the underlying layer of an anti-reflective stack. A device suited for carrying out the method is also described.

The present invention relates to a method of depositing on a substrate in a vacuum an amorphous layer containing mostly fluorine and carbon, in particular an amorphous fluorocarbon layer.

Certain fluorocarbon materials, when used in thin layers, are transparent in the visible spectrum and have a low refractive index, for example polytetrafluoroethylene (n=1.35 at 630 nm).

Their use as a low-index layer in an antireflection treatment is therefore particularly appropriate as they allow a low level of reflection and perfect transparency throughout the visible spectrum. In the field of antireflection coatings on ophthalmic lenses in particular, it is beneficial to use a material having a refractive index lower than that of silica (n˜1.47 at 630 nm), a material that is widely used at present, as this optimizes the efficacy of the antireflection coating at the same time as maintaining a limited number of layers.

However, fluorocarbon materials often have poor adhesion to most other materials. This is the case, for example, when depositing an amorphous fluorocarbon compound such as Teflon® by evaporation in a vacuum. This poor adhesion is impeding the expansion of their use, especially in everyday articles that are used intensively and have to be cleaned frequently, such as ophthalmic lenses.

Another method used industrially is plasma-enhanced chemical vapor deposition (PECVD), which is described in international patent application WO 98/33077, for example. The method is based on using a plasma to dissociate precursor gases and thereby to create free radicals that are able to reassociate to form a homogeneous material adhering to the surface of objects introduced into the reaction chamber. This technique is satisfactory but necessitates the use of costly equipment.

Furthermore, the transparency of fluorocarbon layers obtained by PECVD is disappointing as they are generally of yellowish color.

This is why a new deposition strategy is proposed here, that consists in using an ion gun to eject fluorocarbon or hydrofluorocarbon ions in the form of a beam of accelerated ions that bombards the substrate whilst also supplying the electrons necessary to constitute electrically neutral compounds containing fluorine and carbon.

This is a simple and effective way to make an amorphous fluorocarbon layer with a low refractive index adhere to an optical substrate or underlying layer to constitute an antireflection layer or stack of layers that can be used for the production of ophthalmic lenses having very high resistance to impact and to scratching, perfect transparency and a very low refractive index.

Moreover, this method can easily be used in a conventional evaporation machine, allowing evaporation of the first layers followed directly by the deposition of the amorphous fluorocarbon layer.

Thus, taken as a whole, the invention proposes a method of depositing an amorphous layer containing mostly fluorine and carbon on a substrate in a vacuum, characterized in that it includes a step of depositing said layer by means of an ion gun adapted to eject ions in the form of a beam of accelerated ions created from at least one compound containing fluorine and carbon in gas or saturated vapor form fed to the ion gun.

According to preferred features:
the ion gun is fed with at least one compound containing fluorine and carbon mixed with oxygen or at least one rare gas; and/or
the ion gun is fed with at least one aliphatic or cyclic fluorocarbon compound, at least one aliphatic or cyclic fluorinated hydrocarbon, or a mixture thereof.

The fluorocarbon layer that may be obtained in accordance with the invention consists in an aggregate of compounds essentially consisting of atoms of fluorine and carbon. It is intended to cover the surface of the substrate or an underlying layer continuously with a thickness that typically varies from 1 nm to 500 nm. Among other things, it has a low refractive index and a low dielectric constant.

A fluorocarbon layer of the above kind is amorphous in that the fluorocarbon molecules that constitute it generally do not form polymers or large crystalline structures.

To enhance the efficacy of the method, it is more preferable to use perfluorocyclobutane (c-C₄F₈) or a mixture of that compound with at least one other fluorocarbon compound, in particular tetrafluoromethane (CF₄) or hexafluoromethane (C₂F₆), or at least one rare gas.

The rare gas is preferably argon or xenon.

The positive ions created from a fluorocarbon gas are mostly CF3+, CF2+, CF+, C+ and F+ in proportions that depend firstly on the fluorocarbon gas used and also on the presence of an additive gas.

The method of the invention can also provide a faster rate of deposition by increasing the anode voltage, the effect of which is to facilitate the dissociation of the fluorocarbon gas and to increase the energy of the ions.

The ion gun generally used is of the kind having an annular anode, a filament that serves as the cathode and extends diametrally above the annular anode, and a magnet disposed below the annular anode, which may be a permanent magnet. The gas distributor that feeds the gun with gas is preferably disposed between the anode and the magnet.

Accordingly, electrons are emitted by the cathode and follow a trajectory defined by the lines of the magnetic field. The electrons are accelerated toward a discharge area near the anode, where they collide with the molecules of the compounds containing fluorine and carbon. These collisions cause ionization and dissociation of the compounds containing fluorine and carbon. The ions and electrons form a conductive gas or plasma.

In a context of the above kind, the ions formed are accelerated in all directions in space. They cross the axis of the gun several times before escaping from the discharge area in the form of a divergent beam of ions.

Finally, the positive charge of the ions is neutralized by some of the electrons coming from the cathode, so that when they reach the substrate the electrical current of the beam is virtually zero.

The mode of deposition provided by the invention enables the use of various substrates, which may consist of mineral materials or more advantageously of plastics materials.

The material may in particular be a resin such as the CR-39® resin from PPG Industries, which may in certain cases be covered with an anti-abrasion varnish such as ORMA SUPRA®.

The method may be used to deposit a single amorphous layer containing mostly fluorine and carbon, but the invention encompasses the production of stacked layers with varying refractive indices, comprising a layer containing mostly fluorine and carbon deposited by the method of the invention, with a view to fabricating, among other things, ophthalmic lenses with an antireflection treatment.

When the method of the present invention is used in the context of an antireflection stack, the layer containing mostly fluorine and carbon generally forms the low-index external layer.

The invention may therefore consist in fabricating an antireflection stack by successive steps of physical vapor phase deposition (PVD) in a vacuum of three layers respectively having, from the interior of the stack towards the exterior, a high refractive index/a low refractive index/a high refractive index, this stack of layers preferably corresponding to a stack of type ZrO₂/SiO₂/ZrO₂, where ZrO₂ and SiO₂ designate the materials from which these layers are formed, and then depositing the amorphous external layer containing mostly fluorine and carbon by means of the ion gun.

Antireflection stacks on ophthalmic lenses conventionally include a final antisoiling layer. The deposition of a layer of this kind is not necessarily within the scope of the invention, since the amorphous layer containing mostly fluorine and carbon of the invention already has this antisoiling property.

Each in vacuo PVD step referred to above preferably includes evaporation of the material to be deposited by an electron gun.

In practice, each PVD step is carried out at a pressure less than or equal to 10⁻² Pa.

The invention also relates to the use of the method defined above to improve the adhesion of a low refractive index exterior layer to the underlying layer of an antireflection stack.

The invention finally consists in a device suited to carrying out the method according to the invention characterized in that it includes:
an ion gun;
means for feeding the ion gun with a compound containing fluorine and carbon in gas or vapor form; and
a substrate holder above the ion gun.

The ion gun is preferably of the kind defined above.

The ion gun and the substrate-holder are accommodated in a chamber and the device includes a pumping system for evacuating said chamber.

The device may be complemented by a cold trap adapted to increase the water pumping speed and an electron gun for evaporating by electron bombardment the materials to be deposited.

The features and advantages of the invention will emerge from the following description, which refers to the appended diagrammatic drawings, in which:

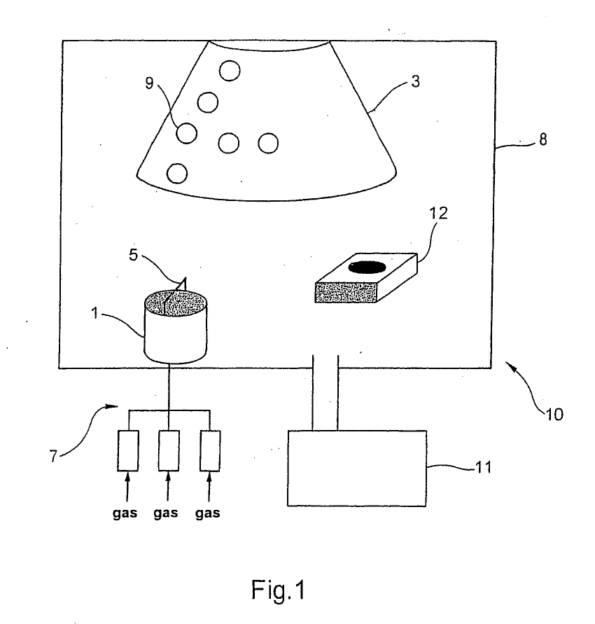

FIG. 1 is a diagram of a device for carrying out the method of the invention,

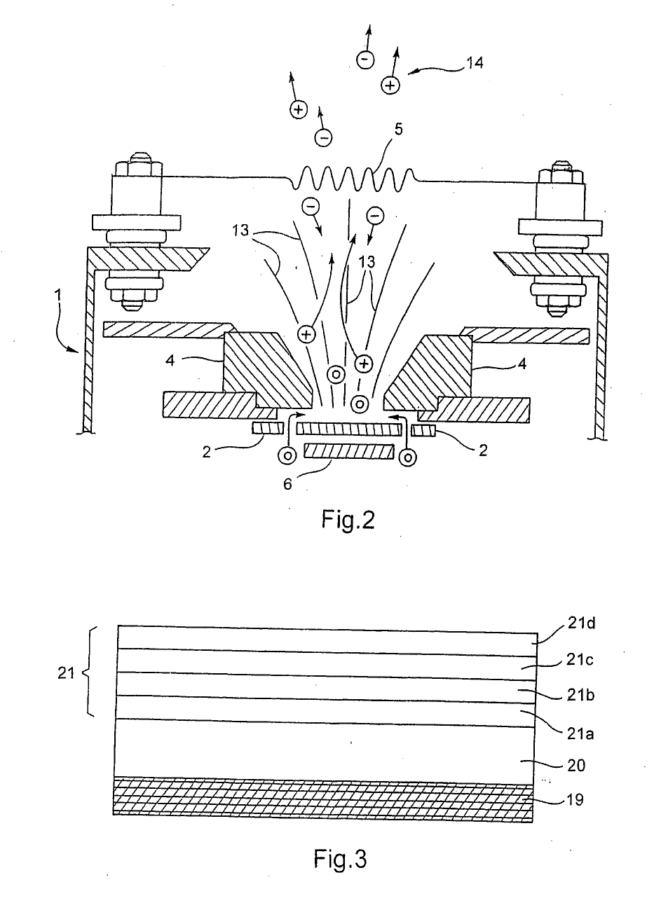

FIG. 2 is a diagram in section of an ion gun that may be used in the method of the invention, and

FIG. 3 shows an antireflection stack produced by a preferred embodiment of the method of the invention.

In the embodiment shown, the device 10 for carrying out the method of deposition on a substrate 9 takes the form of a chamber 8 which may be evacuated and inside which are disposed a MarK II ion gun 1 from Commonwealth Scientific comprising a fixed magnet 6 and, on the axis of the gun, a substrate holder 3 situated in the exit direction of the ions 14.

The substrate 9 is carried by a substrate holder 3 which in practice forms part of a conventional turntable.

The gas supplying the ion gun with compounds containing fluorine and carbon is released below the annular anode 4 by means of a gas distributor 2 consisting of a perforated plate. The quantity of gas is regulated on the upstream side by supply means 7 connected to one or more MKS mass flowmeters.

Electrons are emitted by a cathode 5 and follow approximately the magnetic field lines 13 that may be seen in FIG. 2. They are accelerated toward the discharge area near the anode 4, where they collide with atoms or molecules. Some of these collisions produce ions. The mixture of electrons and ions in the discharge region forms a conductive gas or plasma. The ions formed are accelerated as indicated in FIG. 2 and may cross the axis of the ion gun several times before exiting the source. At the exit they form a divergent beam.

The positive space charge of these ions is then neutralized by some of the electrons from the cathode 5.

A pumping system 11 is provided to evacuate the interior of the deposition chamber 8 and a cold trap (Meissner trap), not shown here to simplify the diagram, is placed inside the enclosure to increase the water pumping rate. It is therefore possible to obtain in a few minutes the pressure of the order of 10⁻² Pa necessary for deposition.

A Leybold ESV6 electron gun 12 with a rotating crucible having four cavities is provided for evaporating by electron bombardment the materials to be deposited.

It is important to note that the cathode 5 takes the form of a filament extending diametrally over the annular anode 4.

FIG. 3 shows one example of a stack that may be obtained by the method of the invention.

In the embodiment shown in this figure, an organic substrate 19 coated with ORMA-SUPRA® anti-abrasion varnish 20 is coated with an antireflection stack comprising alternating thin layers of high and low refractive index 21(a-d).

In the preferred embodiment shown in FIG. 2, the first layer 21a is of a high refractive index material, i.e. a material having a refractive index greater than 1.6. Here this material is zirconium oxide (ZrO₂), which is deposited to a physical thickness that is typically from 35 nm to 75 nm.

The second layer 21b deposited on the first layer 21a here consists of silica (SiO₂), which has a low refractive index, typically with a thickness from 20 nm to 40 nm.

Here the third deposited layer 21c is identical to the first layer 21a (ZrO₂), except for its thickness, which is from 120 nm to 190 nm.

The above three layers are deposited successively by means of the PVD technique defined above using the electron gun 12.

Note that other suitable materials familiar to the person skilled in the art could be used in the first portion of this stack without fundamentally modifying its performance.

In the preferred embodiment, an amorphous fluorocarbon layer 21d formed a low refractive index exterior layer of the stack. It was deposited using an ion gun in the FIG. 1 device. Its thickness was from 70 nm to 110 nm.

It was deposited directly onto the high refractive index third layer 21c by placing the sample directly over the ion gun; it is preferable if the angle between the axis of the stack and that of the ion gun does not exceed 30°. Rotation of the turntable is also possible, of course.

Deposition employed 2 sccm (cm³/min under normal conditions) of c-C₄F₈ in gaseous form, allowing the projection of fluorocarbon ions.

The anode voltage was approximately 100 V and an anode current was obtained from 0.8 A to 1 A, yielding a deposition rate of the order of 3 Angstrom/s for a gun-substrate distance of approximately 30 cm.

Note that it is possible to optimize the deposition yield by introducing a rare gas such as xenon in the gas mixture, or simply by increasing the anode voltage. The effect of these measures is to fractionate further the ions emitted by the gun 1.

The deposited amorphous layer was first inspected with the naked eye: it was transparent.

A very low refractive index was found, of the order of 1.39 at 600 nm for this kind of layer.

Moreover, a water contact angle of more than 90° was obtained.

No trace of abrasion was found during rubbing tests with a flexible cloth under the usual conditions for cleaning ophthalmic lenses.

Adhesion to the underlying layer was entirely satisfactory and in every instance better than the adhesion of a fluorocarbon layer obtained by vacuum evaporation.

It was therefore found that the method of the invention yields antireflection stacks having very dense thin layers and very satisfactory characteristics from the points of view of adhesion and resistance to scratching.

The stacks obtained are therefore perfectly suited to use on ophthalmic lenses.

Of course, the present invention is not limited to the embodiment described and shown, and encompasses any variant execution thereof.

1. Method of depositing an amorphous layer containing mostly fluorine and carbon on a substrate in a vacuum, characterized in that it includes a step of depositing said layer by means of an ion gun adapted to eject ions in the form of a beam of accelerated ions created from at least one compound containing fluorine and carbon in gas or saturated vapor form fed to the ion gun.

2. Method according to claim 1, characterized in that the layer containing mostly fluorine and carbon is the low index exterior layer of an antireflection stack deposited on the substrate.

3. Method according to claim 1, characterized in that the ion gun is fed with at least one compound containing fluorine and carbon mixed with oxygen or at least one rare gas.

4. Method according to claim 1, characterized in that the ion gun is fed with at least one aliphatic or cyclic fluorocarbon compound, at least one aliphatic or cyclic fluorinated hydrocarbon, or a mixture thereof.

5. Method according to claim 4, characterized in that the ion gun is fed with perfluorocyclobutane (c-C₄F₈) or a mixture thereof with at least one other fluorocarbon compound, in particular tetrafluoromethane (CF₄) or hexafluoromethane (C₂F₆), or at least one rare gas.

6. Method according to claim 1, characterized in that the substrate is a plastics material substrate.

7. Method according to claim 2, characterized in that it consists in fabricating an antireflection stack by the following steps:
physical vapor-phase deposition (PVD) in a vacuum of three layers respectively having, from the interior toward the exterior, a high refractive index/a low refractive index/a high refractive index, preferably of the type ZrO₂/SiO₂/ZrO₂;
depositing the amorphous external layer containing mostly fluorine and carbon using the ion gun.

8. Method according to claim 7, characterized in that each in vacuo PVD step includes evaporation by electron bombardment of the material to be deposited.

9. Method according to claim 7 or claim 8, characterized in that each deposition step is carried out at a pressure less than or equal to 10⁻² Pa.

10. Use of the method according to any one of claims 1 to 9 claim 1 to improve the adhesion of a low refractive index exterior layer to the underlying layer of an antireflection stack.

11. Device suited to carrying out the method according to any one of claims 1 to 9 claim 1 and including:
an ion gun (1);
means (7) for feeding the ion gun with a compound containing fluorine and carbon; and
a substrate holder (3) above the ion gun.

12. Device according to claim 11, characterized in that the ion gun includes an annular anode (4), a filamentary cathode (5) extending diametrically above the annular anode, and a magnet (6) below the annular anode.

13. Device according to claim 12, characterized in that the ion gun (1) includes a gas distributor (2) between the annular anode and the magnet.

14. Device according to claim 12, characterized in that it includes a chamber (8) in which the ion gun (1) and the substrate holder (3) are accommodated and a pumping system (11) for evacuating the chamber.

15. Device according to claim 14, characterized in that it includes a cold trap adapted to increase the water pumping rate.

16. Device according to claim 11, characterized in that it includes an electron gun (12) for evaporating by electron bombardment the materials to be deposited.

17. Method according to claim 2, characterized in that the ion gun is fed with at least one compound containing fluorine and carbon mixed with oxygen or at least one rare gas.

18. Method according to claim 8, characterized in that each deposition step is carried out at a pressure less than or equal to 10⁻² Pa.

19. Method according to claim 17, characterized in that it consists in fabricating an antireflection stack by the following steps:
physical vapor-phase deposition (PVD) in a vacuum of three layers respectively having, from the interior toward the exterior, a high refractive index/a low refractive index/a high refractive index, preferably of the type ZrO₂/SiO₂/ZrO₂;
depositing the amorphous external layer containing mostly fluorine and carbon using the ion gun.

20. Device according to claim 13, characterized in that it includes a chamber (8) in which the ion gun (1) and the substrate holder (3) are accommodated and a pumping system (11) for evacuating the chamber.
